(19) United States
(12) Patent Application Publication
(10) Pub. No.: US 2023/0207288 A1
(43) Pub. Date: Jun. 29, 2023

(54) SUBSTRATE TREATMENT APPARATUS

(71) Applicant: Semes Co. Ltd., Cheonan-si (KR)

(72) Inventors: Sang-Kee LEE, Cheonan-si (KR); So Hyung Jeong, Cheonan-si (CN)

(73) Assignee: Semes Co. Ltd., Cheonan-si (KR)

(21) Appl. No.: 18/147,462

(22) Filed: Dec. 28, 2022

(30) Foreign Application Priority Data
Dec. 29, 2021 (KR) 10-2021-0191337
Jun. 23, 2022 (KR) 10-2022-0077080

(51) Int. Cl. H01J 37/32

(52) U.S. Cl. CPC H01J 37/32724; H01J 37/32082; H01J 37/32513; H01J 2237/20235; H01J 2237/2005; H01J 37/32495

(57) ABSTRACT

The inventive concept provides an apparatus for treating a substrate. A substrate treatment apparatus according to an embodiment includes a housing having a treatment space in which the substrate is treated, a support unit that supports the substrate in the treatment space, and a gas supply unit that supplies a gas to the treatment space, wherein a heat transfer flow path that supplies a heat transfer medium to the substrate supported by the support unit, a pin hole defining an elevation path of a lift pin that elevates the substrate supported by the support unit, and a connection portion allowing the heat transfer flow path and the pin hole to be in communication with each other are formed inside the support unit, and the connection portion includes a porous structure.

### CROSS-REFERENCE TO RELATED APPLICATIONS

A claim for priority under 35 U.S.C. § 119 is made to Korean Patent Application No. 10-2021-0191337 filed on Dec. 29, 2021 and Korean Patent Application No. 10-2022-0077080 filed on Jun. 23, 2022, in the Korean Intellectual Property Office, the entire contents of which are hereby incorporated by reference.

### BACKGROUND

Embodiments of the inventive concept described herein relate to an apparatus for treating a substrate, and more particularly, to a substrate treatment apparatus for plasma-treating a substrate.

Plasma refers to an ionized gaseous state including ions, radicals, electrons, and the like. The plasma is generated by very high temperature, strong electric fields, or radio frequency (RF) electromagnetic fields. A semiconductor device manufacturing process may include an etching process of removing a thin film formed on a substrate, such as a wafer, using the plasma. The etching process is performed as ions and/or radicals of the plasma collide with a thin film on the substrate or react with the thin film.

In a process of treating the substrate using the plasma, a temperature of the substrate needs to be maintained constant. To maintain a constant temperature of the substrate, a temperature adjustment unit such as a heater or a refrigerant flow path may be provided in a support unit that supports the substrate. Further, a heat transfer gas flow path for supplying a heat transfer gas to a lower surface of the substrate may be generally provided for efficient heat exchange between the temperature adjustment unit and the substrate.

While the plasma and the thin file on the substrate collide with each other, the temperature of the substrate increases. Accordingly, the heat transfer gas is supplied to the lower surface of the substrate while the substrate is treated using the plasma. The plasma may penetrate into the support unit by penetrating into a minute space between the lower surface of the substrate and an upper surface of the support unit. The plasma penetrating into the support unit affects a member provided in the support unit and vulnerable to arcing.

A pin hole functioning as a movement flow path of a lift pin that elevates the substrate from the support unit is a hole penetrating the upper surface of the support unit and is formed inside the support unit. Accordingly, the plasma penetrates into the pin hole and affects the pin hole and members arranged adjacent to the pin hole. The pin hole and the members arranged adjacent to the pin hole are exposed to the plasma for a long time, thereby causing the arcing. In particular, when the plasma is formed by applying radio frequency (RF) power having a high voltage to satisfy an etching rate of a recent high aspect ratio, the pin hole and the members arranged adjacent to the pin hole are exposed to strong plasma. Accordingly, an arcing phenomenon of the pin hole and the members arranged adjacent to the pin hole is intensified.

### SUMMARY

Embodiments of the inventive concept provide a substrate treatment apparatus which may minimize occurrence of an arcing phenomenon by plasma.

Further, embodiments of the inventive concept also provide a substrate treatment apparatus which may minimize occurrence of the arcing phenomenon by the plasma in the vicinity of a pin hole.

Further, embodiments of the inventive concept also provide a substrate treatment apparatus which may supply a heat transfer medium to a lower surface of a substrate through the pin hole to adjust a temperature of the substrate, and at the same time, adjust a temperature inside the pin hole.

The aspect of the inventive concept is not limited thereto, and other unmentioned aspects of the inventive concept may be clearly appreciated by those skilled in the art from the following description.

The inventive concept provides a substrate treatment apparatus. According to an embodiment, a substrate treatment apparatus includes a housing having a treatment space in which the substrate is treated, a support unit that supports the substrate in the treatment space, and a gas supply unit that supplies a gas to the treatment space, wherein a heat transfer flow path that supplies a heat transfer medium to the substrate supported by the support unit, a pin hole defining an elevation path of a lift pin that elevates the substrate supported by the support unit, and a connection portion allowing the heat transfer flow path and the pin hole to be in communication with each other are formed inside the support unit, and the connection portion includes a porous structure.

According to an embodiment, the support unit may include a support plate that supports the substrate, and a body which is positioned below the support plate and in which high frequency power is applied to generate plasma in the treatment space, a lift pin bush having a hollow therein forming a portion of the pin hole may be disposed inside the body, and the connection portion may be formed on a side surface of the lift pin bush.

According to an embodiment, the connection portion may be formed integrally with the side surface of the lift pin bush.

According to an embodiment, an O ring that seals an outer surface of the lift pin and a side surface of the hollow may be disposed in the hollow, and the O ring is positioned below the connection portion when viewed from the front side.

According to an embodiment, the heat transfer flow path may include a main flow path which is formed inside the body and through which the heat transfer medium circulates, a first flow path that is connected to the main flow path, is formed in a vertical direction inside the body and the support plate, and supplies the heat transfer medium to a lower surface of the substrate, and a second flow path formed inside the body and connecting the main flow path and the connection portion.

According to an embodiment, a diameter of the second flow path may correspond to a diameter of the connection portion or may be smaller than the diameter of the connection portion.

According to an embodiment, a lower surface of the support plate and an upper surface of the body may adhere to each other by an adhesive layer.

According to an embodiment, each of the lift pin bush and the connection portion may include a material having relatively higher plasma resistance than the adhesive layer and the second flow path.

According to an embodiment, a material of each of the lift pin bush and the connection portion may include ceramics.

According to an embodiment, a surface of the second flow path may be anodized.

According to an embodiment, the main flow path may include a central flow path formed in a central region including a center of the body, and an edge flow path formed in an edge region surrounding the central region, and the second flow path may connect the central flow path and/or the edge flow path and the connection portion.

According to an embodiment, the plurality of pin holes may be formed inside the support unit, the plurality of second flow paths may be formed inside the body, and the plurality of pin holes may be in fluid communication with the plurality of second flow paths, respectively.

Further, the inventive concept also provides a substrate treatment apparatus. According to an embodiment, a substrate treatment apparatus includes a housing having a treatment space in which the substrate is treated, a support unit that supports the substrate in the treatment space, a gas supply unit that supplies a gas to the treatment space, and a plasma source that generates plasma by exciting the gas, wherein the support unit includes a heat transfer flow path that is formed inside the support unit and supplies a heat transfer medium to the substrate supported by the support unit, a lift pin bush disposed inside the support unit and having a hollow formed therein, and a lift pin that is elevated through the hollow and elevates the substrate supported by the support unit, a connection portion including a porous structure is formed on a side surface of the lift pin bush, and the heat transfer flow path is connected to the connection portion.

According to an embodiment, the connection portion and the lift pin bush may be simultaneously sintered and integrally formed.

According to an embodiment, an upper portion of the lift pin bush may have a first diameter, a lower portion of the lift pin bush may have a second diameter greater than the first diameter, and the connection portion may be formed above the lift pin bush.

According to an embodiment, the support unit may further include a support plate that supports the substrate, and a body which is positioned below the support plate and in which high frequency power is applied to generate the plasma in the treatment space, the heat transfer flow path may be formed inside the body, the lift pin bush may be disposed inside the body, an upper surface of the lift pin bush may be positioned between an upper surface of the body and a lower surface of the support plate, and the lower surface of the support plate and the upper surface of the body and the lower surface of the support plate and the upper surface of the lift pin bush may adhere to each other by an adhesive layer.

According to an embodiment, each of the lift pin bush and the connection portion may include a material having relatively stronger plasma resistance than the adhesive layer.

According to an embodiment, an O ring that seals an outer surface of the lift pin and a side surface of the hollow may be disposed in the hollow.

According to an embodiment, the O ring may be positioned below the connection portion when viewed from the front side.

Further, the inventive concept also provides a substrate treatment apparatus. According to an embodiment, a substrate treatment apparatus includes a housing having a treatment space in which the substrate is treated, a support unit that supports the substrate in the treatment space, a gas supply unit that supplies a gas to the treatment space, and a plasma source that generates plasma by exciting the gas, wherein the support unit includes a support plate that supports the substrate, a body which is positioned below the support plate and in which high frequency power is applied to generate the plasma in the treatment space, a heat transfer flow path that is formed inside the body and supplies a heat transfer medium to the substrate supported by the support unit, a lift pin bush disposed inside the body and having a hollow formed therein, and a lift pin that is elevated through the hollow and elevates the substrate supported by the support unit from the support plate, the heat transfer flow path includes a main flow path which is formed inside the body and through which the heat transfer medium circulates, a first flow path that is connected to the main flow path, is formed inside the body and the support plate in a vertical direction, and supplies the heat transfer medium to a lower surface of the substrate, and a second flow path that is formed inside the body and allows the main flow path and the hollow to be in fluid communication with each other, a connection portion having a porous structure may be integrally formed on a side surface of the lift pin bush, and one end of the second flow path may be connected to the connection portion.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is schematic drawing view illustrating a substrate treatment apparatus according to an embodiment of the inventive concept;

FIG. 2 is a schematic view illustrating a process chamber of FIG. 1 according to the embodiment;

FIG. 3 is a schematic view illustrating a main flow path of FIG. 2 according to the embodiment when viewed from an upper portion;

FIG. 4 is a schematic perspective view illustrating a lift pin bush of FIG. 2 according to the embodiment;

FIG. 5 is a partially enlarged view of a support unit of FIG. 2 according to the embodiment;

FIG. 6 is a schematic view illustrating a state in which a heat transfer medium flows inside the pin hole of FIG. 5 according to the embodiment;

FIG. 7 is a schematic view illustrating a main flow path of FIG. 2 according to another embodiment when viewed from the upper portion;

FIG. 8 is a schematic view illustrating a process chamber of FIG. 2 according to another embodiment; and

FIG. 9 is a schematic view illustrating the main flow path of FIG. 7 according to the embodiment when viewed from the upper portion.

### DETAILED DESCRIPTION

Hereinafter, embodiments of the inventive concept will be described in more detail with reference to the accompanying drawings. Embodiments of the inventive concept may be modified in various forms, and the scope of the inventive concept should not be construed as being limited by the embodiments described below. The present embodiments are provided to more completely describe the inventive concept to those skilled in the art. Thus, the shapes and the like of components in the drawings are exaggerated in order to emphasize a clearer description.

The terms such as first and second may be used to describe various elements, but the elements are not limited to the terms. The terms may be used only for the purpose of distinguishing one element from another element. For example, while not deviating from the scope of the inventive concept, a first element may be named a second element, and similarly, the second element may be named the first element.

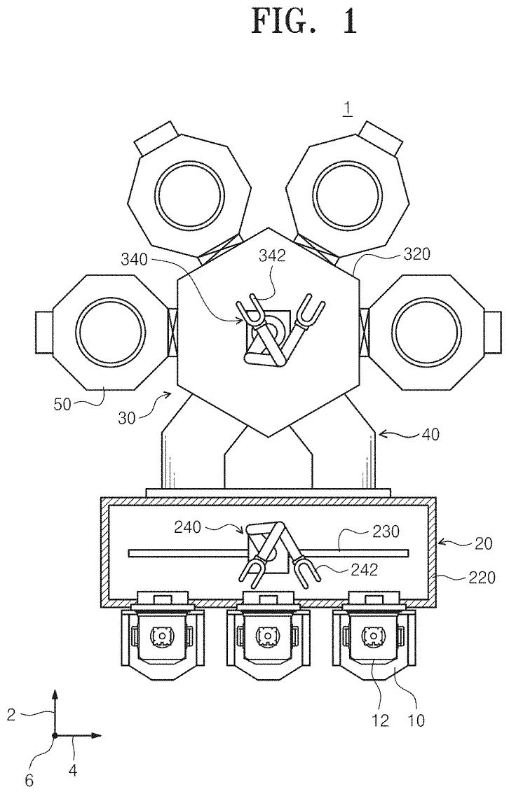

Hereinafter, embodiments of the inventive concept will be described in detail with reference to FIGS. 1 to 9.

FIG. 1 is a schematic view illustrating a substrate treatment apparatus according to an embodiment of the inventive concept. Referring to FIG. 1, a substrate treatment apparatus 1 according to the embodiment of the inventive concept may include a load port 10, a normal pressure transfer module 20, a vacuum transfer module 30, a load lock chamber 40, and a process chamber 50.

The load port 10 may be disposed on one side of the normal pressure transfer module 20, which will be described below. At least one load port 10 may be disposed on the one side of the normal pressure transfer module 20. The number of load ports 10 may be increased or decreased according to process efficiency and a footprint condition.

A container 12 may be placed on the load port 10. The container 12 may be loaded onto the load port 10 or unloaded from the load port 10 by an operator or a transfer unit (not illustrated) such as an overhead transfer apparatus (OHT), an overhead conveyor, or an automatic guided vehicle. The container 12 may include various types of containers according to the types of products to be stored. An airtight container such as a front opening unified pod (FOUP) may be used as the container 12.

The normal pressure transfer module 20 and the vacuum transfer module 30 may be arranged in a first direction 2. Hereinafter, a direction that is perpendicular to the first direction 2 when viewed from the top is defined as a second direction 4. Further, a direction perpendicular to a plane including both the first direction 2 and the second direction 4 is defined as a third direction 6. As an example, the third direction 6 may refer to a direction that is perpendicular to the ground.

The normal pressure transfer module 20 may transfer a substrate “W” between the container 12 and the load lock chamber 40, which will be described below. According to the embodiment, the normal pressure transfer module 20 may extract the substrate “W” from the container 12 to transfer the substrate “W” to the load lock chamber 40 or extract the substrate “W” from the load lock chamber 40 to transfer the substrate “W” into the container 12.

The normal pressure transfer module 20 may include a transfer frame 220 and a first transfer robot 240. The transfer frame 220 may be disposed between the load port 10 and the load lock chamber 40. The load port 10 may be in contact with the transfer frame 220. The inside of the transfer frame 220 may maintain a normal pressure atmosphere. According to the embodiment, the inside of the transfer frame 220 may be made into an atmospheric pressure atmosphere.

A transfer rail 230 is disposed in the transfer frame 220. A lengthwise direction of the transfer rail 230 may be parallel to a lengthwise direction of the transfer frame 220. The first transfer robot 240 may be positioned on the transfer rail 230.

The first transfer robot 240 may transfer the substrate “W” between the container 12 seated on the load port 10 and the load lock chamber 40, which will be described below. The first transfer robot 240 may move forward and rearward in the second direction 4 along the transfer rail 230. Further, the first transfer robot 240 may moves in a vertical direction (for example, the third direction 6).

The first transfer robot 240 has a first transfer hand 242. The substrate “W” is placed on the first transfer hand 242. The first transfer hand 242 may move forward and rearward and/or rotate on a horizontal plane. The first transfer robot 240 may have a plurality of first transfer hands 242. The plurality of first transfer hands 242 may be arranged spaced apart from each other in the vertical direction.

The vacuum transfer module 30 may be disposed between the load lock chamber 40, which will be described below, and the process chamber 50. The vacuum transfer module 30 may include a transfer chamber 320 and a second transfer robot

The inside of the transfer chamber 320 may be maintained at a vacuum atmosphere. The second transfer robot 340 may be disposed in the transfer chamber 320. For example, the second transfer robot 340 may be disposed in a center of the transfer chamber 320. The second transfer robot 340 transfers the substrate “W” between the load lock chamber 40, which will be described below, and the process chamber 50. Further, the second transfer robot 340 may transfer the substrate “W” between the process chambers 50.

The second transfer robot 340 may move in the vertical direction (for example, the third direction 6). The second transfer robot 340 may have a second transfer hand 342 that moves forward and rearward and/or rotates on the horizontal plane. The substrate “W” is placed on the second transfer hand 342. The second transfer robot 340 may have a plurality of second transfer hands 342. The plurality of second transfer hands 342 may be arranged spaced apart from each other in the vertical direction.

At least one process chamber 50 may be connected to the transfer chamber 320. According to the embodiment, the transfer chamber 320 may have a polygonal shape. The load lock chamber 40, which will be described below, and the process chamber 50 may be arranged in a periphery of the transfer chamber 320. For example, as illustrated in FIG. 1, the transfer chamber 320 having a hexagonal shape may be disposed at a center of the vacuum transfer module 30, and the load lock chamber 40 and the process chamber 50 may be arranged along the periphery thereof. Unlike the above description, the shape of the transfer chamber 320 and the number of process chambers 50 may be variously changed according to user's requirements or process requirements.

The load lock chamber 40 may be disposed between the transfer frame 220 and the transfer chamber 320. The load lock chamber 40 has a buffer space in which the substrate “W” is exchanged between the transfer frame 220 and the transfer chamber 320. For example, the substrate “W”, which has been treated in the process chamber 50, may temporarily stay in the buffer space of the load lock chamber 40. Further, the substrate “W”, which is extracted from the container 12 and is scheduled to be treated, may temporarily stay in the buffer space of the load lock chamber 40.

As described above, the inside of the transfer frame 220 may be maintained in an atmospheric pressure atmosphere, and the inside of the transfer chamber 320 may be maintained in a vacuum pressure atmosphere. Accordingly, the load lock chamber 40 may be disposed between the transfer frame 220 and the transfer chamber 320, and the internal atmosphere of the load lock chamber 40 may be switched between the atmospheric pressure and the vacuum pressure.

The process chamber 50 is connected to the transfer chamber 320. The process chamber 50 may be provided as a plurality of process chambers 50. The process chamber 50 may be a chamber in which a predetermined process is performed on the substrate “W”. According to the embodiment, the process chamber 50 may be a chamber in which the substrate “W” is treated using plasma.

For example, the process chamber 50 may be a chamber in which an etching process of removing a thin film on the substrate “W” using plasma, an ashing process of removing a photoresist film, a deposition process of forming the thin film on the substrate “W”, a dry cleaning process, an atomic layer deposition (ALD) process of depositing an atomic layer on the substrate, or an atomic layer etching (ALE) process of etching the atomic layer on the substrate are performed. However, the inventive concept is not limited thereto, and a plasma treatment process performed in the process chamber 50 may be variously modified to known plasma treatment processes.

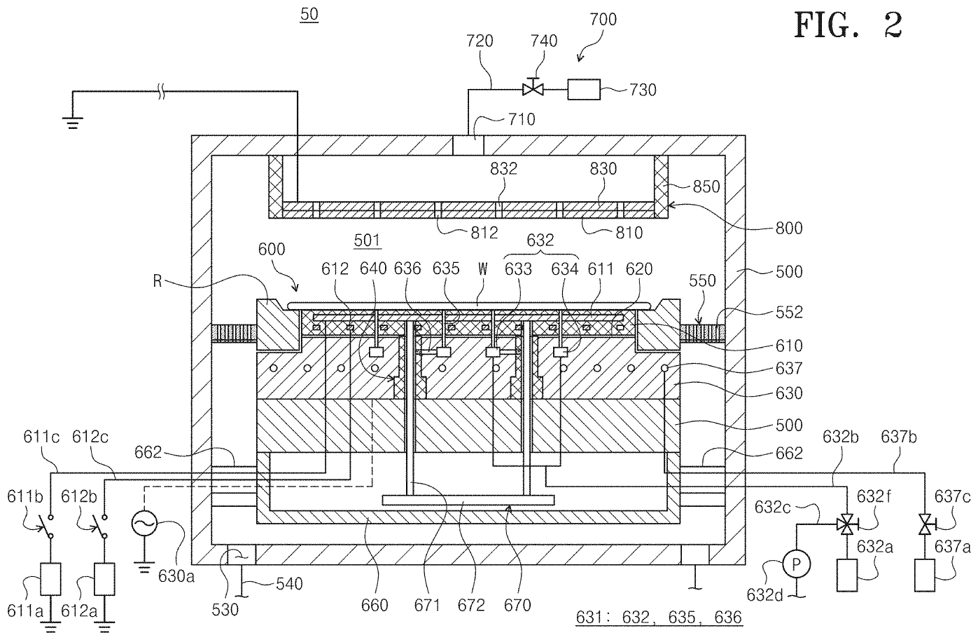

FIG. 2 is a schematic view illustrating a process chamber of FIG. 1 according to the embodiment. Referring to FIG. 2, the substrate “W” may be plasma-treated in the process chamber 50 according to the embodiment. The process chamber 50 may include a housing 500, a support unit 600, a gas supply unit 700, and a shower head unit 800.

The housing 500 may have a shape of which an inside is sealed. The housing 500 has an internal space. The internal space of the housing 500 functions as a treatment space 501 in which the substrate “W” is treated. The treatment space 501 may be maintained in a substantially vacuum atmosphere while the substrate “W” is treated. A material of the housing 500 may include a metal. According to the embodiment, the material of the housing 500 may include aluminum. Further, the housing 500 may be grounded.

A carrying inlet (not illustrated) may be formed on one side wall of the housing 500. The carrying inlet (not illustrated) functions as a space through which the substrate “W” is carried in or out from the treatment space 501. The carrying inlet (not illustrated) may be selectively opened or closed by a door assembly that is not illustrated.

An exhaust hole 530 may be formed in a bottom surface of the housing 500. The exhaust hole 530 is connected to an exhaust line 540. A pressure reducing member that is not illustrated may be installed in the exhaust line 540. The pressure reducing member (not illustrated) may be any one of widely known pumps. When the pressure reducing member (not illustrated) forms a negative pressure in the exhaust line 540, gas and process impurities (byproducts) supplied to the treatment space 501 may be discharged from the treatment space 501 while sequentially passing through the exhaust hole 530 and the exhaust line 540. Further, the pressure reducing member (not illustrated) may adjust a pressure of the treatment space 501 by adjusting a negative pressure state of the treatment space 501.

An exhaust baffle 550 may be disposed above the exhaust hole 530.

The exhaust baffle 550 may be disposed between a side wall of the housing 500 and the support unit 600, which will be described below. The exhaust baffle 550 may have a substantially ring shape when viewed from the top. At least one baffle hole 552 may be formed in the exhaust baffle 550. The baffle hole 552 may pass through upper and lower surfaces of the exhaust baffle 550. The gas, the process impurities, and the like of the treatment space 501 may flow to the exhaust hole 530 and the exhaust line 540 while passing through the baffle hole 552.

The support unit 600 is disposed inside the housing 500. The support unit 600 may be disposed in the treatment space 501. The support unit 600 may be disposed spaced a predetermined distance from the bottom surface of the housing 500 in an upward direction. The support unit 600 supports the substrate “W”. The support unit 600 may include an electrostatic chuck that adsorbs the substrate “W” using an electrostatic force. Unlike this, the support unit 600 may support the substrate “W” in various methods such as vacuum adsorption or mechanical clamping. Hereinafter, an example of the support unit 600 including the electrostatic chuck will be described.

The support unit 600 may include the electrostatic chuck, an insulation plate 650, and a lower cover 660.

The electrostatic chuck supports the substrate “W”. The electrostatic chuck may include a support plate 610 and a body 630. The support plate 610 is positioned at an upper portion of the support unit 600. The support plate 610 may be a disk-shaped dielectric substance. The substrate “W” is placed on an upper surface of the support plate 610. According to the embodiment, the upper surface of the support plate 610 may have a smaller radius than that of the substrate “W”. When the substrate

“W” is placed on the upper surface of the support plate 610, an edge region of the substrate “W” may be located outside the support plate 610.

A material of the support plate 610 may include a material having strong plasma resistance. According to the embodiment, the material of the support plate 610 may include ceramics.

An electrode 611 and a heater 612 are arranged inside the support plate 610. According to the embodiment, the electrode 611 may be positioned inside the support plate 610 above the heater 612. The electrode 611 is electrically connected to a first power source 611a. The first power source 611a may include a direct current (DC) power source. A first switch 611b is installed between the electrode 611 and the first power source 611a. When the first switch 611b is turned on, the electrode 611 may be electrically connected to the first power source 611a, and a DC current may flow in the electrode 611. An electrostatic force is applied between the electrode 611 and the substrate “W” by the current flowing in the electrode 611. Accordingly, the substrate “W” is adsorbed to the support plate 610.

The heater 612 is electrically connected to a second power source 612a. A second switch 612b is installed between the heater 612 and the second power source 612a. When the second switch 612b is turned on, the heater 612 may be electrically connected the second power source 612a. The heater 612 may generate heat by resisting a current supplied from the second power source 612a. The heat generated by the heater 612 is transferred to the substrate “W” by means of the support plate 610. The substrate “W” placed on the support plate 610 may be maintained at a predetermined temperature by the heat generated by the heater 612. It has been described in the above-described example that the heater 612 is positioned inside the support plate 610, but the inventive concept is not limited thereto. For example, the heater 612 may not be positioned inside the support plate 610.

The body 630 is located below the support plate 610. The body 630 and the support plate 610 may adhere to each other by an adhesive layer 620. According to the embodiment, an upper surface of the body 630 and a lower surface of the support plate 610 may adhere by the adhesive layer 620. Further, according to the embodiment, the lower surface of the support plate 610 and an upper surface of a lift pin bush 640, which will be described below, may adhere by the adhesive layer 620. The adhesive layer 620 according to the embodiment may include silicone adhesive.

The body 630 may have a disk shape. The upper surface of the body 630 may be stepped such that a central region is higher than an edge region. A central region of an upper portion of the body 630 may have an area corresponding to a bottom surface of the support plate 610. A central region of an upper surface of the body 630 may adhere to the lower surface of the support plate 610 by the adhesive layer 620. Further, a ring member “R”, which will be described below, may be positioned in an edge region of the upper surface of the body 630.

The body 630 may include a conductive material. For example, a material of the body 630 may include aluminum. The body 630 may be a metallic plate.

The body 630 may be electrically connected with a third power source 630a. The third power source 630a may be a high frequency power source that generates high frequency power. For example, the high frequency power source may be a radio frequency (RF) power source. The RF power source may be a high bias power RF power source.

The body 630 receives the high frequency power from the third power source 630a. Accordingly, the body 630 may function as an electrode that generates an electric field. According to the embodiment, the body 630 may function as a lower electrode of a plasma source, which will be described below. However, the inventive concept is not limited thereto, and the body 630 may be grounded and thus function as a lower electrode.

The ring member “R” has a ring shape. According to the embodiment, the ring member “R” may be a focus ring. The ring member “R” is disposed in an edge region of the electrostatic chuck. The ring member “R” may be disposed above the edge region of the body 630. Further, the ring member “R” is disposed along a periphery of the support plate 610.

An upper surface of the ring member “R” may be stepped. According to the embodiment, an inner portion of the upper surface of the ring member “R” may be positioned at the same height as the upper surface of the support plate 610. Further, the inner portion of the upper surface of the ring member “R” may support a lower surface of the edge region of the substrate “W” positioned outside the support plate 610. An outer portion of the upper surface of the ring member “R” may surround a side surface of the edge region of the substrate “W”.

A pin hole may be formed inside the support unit 600. According to the embodiment, the pin hole may be a through-hole passing through the inside of the support unit 600 in the vertical direction. For example, the pin hole may be formed from the upper surface of the support plate 610 to a lower surface of the insulation plate 650, which will be described below. The pin hole functions as an elevation path through which a lift pin 671, which will be described below, moves in the vertical direction.

A heat transfer flow path 631 may be positioned inside the support unit 600. According to the embodiment, the heat transfer flow path 631 may be positioned inside the electrostatic chuck. The heat transfer flow path 631 supplies a heat transfer medium to the lower surface of the substrate “W” supported by the support plate 610. The heat transfer medium may be a fluid supplied to the lower surface of the substrate “W” to solve the temperature non-uniformity of the substrate “W” while the substrate

“W” is plasma-treated. Further, the heat transfer medium may serve as a medium through which the heat transferred from the plasma to the substrate “W” is transferred from the substrate “W” to the support plate 610 and the ring member “R” while the substrate “W” is plasma-treated.

The heat transfer medium may include an inert gas. According to the embodiment, the heat transfer medium may include a helium (He) gas. However, the inventive concept is not limited thereto, and the heat transfer medium may include various types of gases or liquids.

The heat transfer flow path 631 may include a main flow path 632, a first flow path 635, and a second flow path 636.

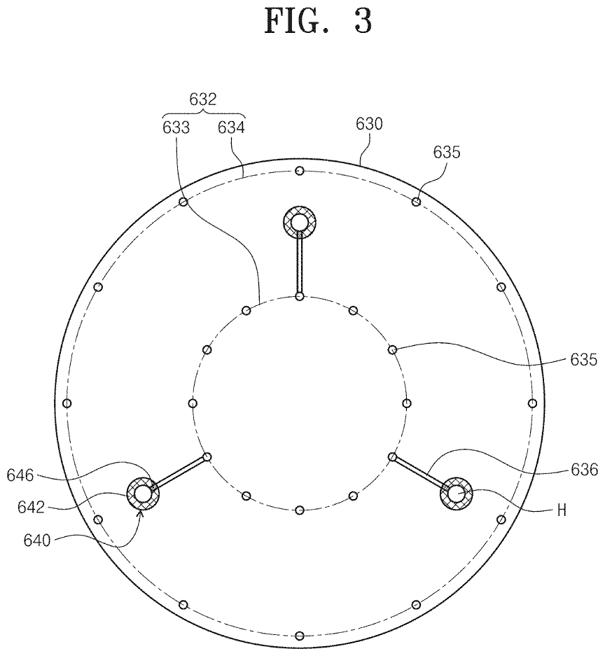

FIG. 3 is a schematic view illustrating a main flow path of FIG. 2 according to the embodiment when viewed from the upper portion. A one-dot chain line illustrated in FIG. 3 briefly illustrates the main flow path 632. Hereinafter, the heat transfer flow path according to the embodiment of the inventive concept will be described in detail with reference to FIGS. 2 and 3.

The main flow path 632 may be a passage through which the heat transfer medium circulates. The main flow path 632 may be positioned inside the body 630. According to the embodiment, when viewed from the front side, the main flow path 632 may be positioned at a height corresponding to an upper portion 642 of the lift pin bush 640, which will be described below. According to the embodiment, the main flow path 632 may be formed by perforating an inside of the body 630. However, the inventive concept is not limited thereto, and the main flow path 632 may be buried into the body 630 in the form of a pipe. The main flow path 632 may be provided above a cooling flow path 637, which will be described below, inside the body 630.

The main flow path 632 may include a central flow path 633 and an edge flow path 634. The central flow path 633 may be positioned in a central region of the body 630 including a center of the body 630. The central flow path 633 may have a substantially circular shape when viewed from the top. The edge flow path 634 may be positioned in an edge region of the body 630 surrounding the central region of the body 630. The edge flow path 634 may have a substantially circular shape when viewed from the top.

The central flow path 633 and the edge flow path 634 are connected to a supply line 632b. The supply line 632b is connected to a supply source 632a. The heat transfer medium is stored in the supply source 632a. Accordingly, the heat transfer medium stored in the supply source 632a may be supplied to the central flow path 633 and the edge flow path 634 through the supply line 632b. Further, a recovery line 632c may be connected to the supply line 632b. The recovery line 632c may recover the heat transfer medium. A pump 632d may be installed in the recovery line 632c. The pump 632d may be a widely known pump applying a negative pressure. A valve 632f may be installed in a region in which the supply line 632b and the recovery line 632c are connected to each other. According to the embodiment, the valve 632c may be a three-way valve. As opening or closing of the valve 632c is adjusted, the heat transfer medium may be supplied to the central flow path 633 and the edge flow path 634 or the heat transfer medium may be recovered from the central flow path 633 and the edge flow path 634.

The lengthwise direction of the first flow path 635 may be the vertical direction. The first flow path 635 may be formed inside the support plate 610 and the body 630. The first flow path 635 may be formed from the upper surface of the support plate 610 to the upper portion of the body 630. The first flow path 635 may be provided as a plurality of first flow paths 635. The plurality of first flow paths 635 may be arranged spaced a predetermined interval from each other.

One end of the first flow path 635 is connected to the main flow path 632. The first flow path 635 may be in fluid communication with the main flow path 632. For example, a portion of the first flow path 635 may be connected to the central flow path 633, and the other portion of the first flow path 635 may be connected to the edge flow path 634. The heat transfer medium circulating in insides of the central flow path 633 and the edge flow path 634 may be supplied to the lower surface of the substrate “W” supported by the support plate 610 through the first flow path 635.

An inner surface of the second flow path 636 may be anodized. The second flow path 636 may be formed inside the body 630. According to the embodiment, when viewed from the front side, the second flow path 636 may be positioned at a height corresponding to the upper portion 642 of the lift pin bush 640, which will be described below. One end of the second flow path 636 may be connected to the main flow path 632. According to the embodiment, one end of the second flow path 636 may be connected to the central flow path 633.

The other end of the second flow path 636 may be connected to the lift pin bush 640, which will be described below. For example, the other end of the second flow path 636 may be connected to a side surface of the lift pin bush 640. The other end of the second flow path 636 may be connected to a connection member 662 which is formed on a side surface of the lift pin bush 640 and will be described below. A portion of the heat transfer medium circulating in the inside of the central flow path 633 may be supplied to a hollow formed inside the lift pin bush 640 through the second flow path 636. A detailed description of a mechanism in which the heat transfer medium flows through the second flow path 636 will be made below.

The cooling flow path 637 may be positioned inside the body 630. The cooling flow path 637 may be positioned below the heat transfer flow path 631. The cooling flow path 637 may be a passage through which a cooling fluid circulates. The cooling flow path 637 may have a spiral shape. Optionally, the cooling flow path 637 may be arranged such that flow paths having ring shapes having different radii share the same center. The cooling flow path 637 is connected to a cooling fluid supply source 637a through a cooling fluid supply line 637b.

The cooling fluid is stored in the cooling fluid supply source 637a. For example, the cooling fluid may be cooling water. A cooler that is not illustrated may be installed in the cooling fluid supply source 637a. The cooler (not illustrated) may cool the cooling fluid to a predetermined temperature. As described above, the cooler (not illustrated) may be installed in the cooling fluid supply line 637b. A cooling valve 637c is installed in the cooling fluid supply line 637b. The cooling valve 637c may be an opening or closing valve. The cooling fluid is supplied to the cooling flow path 637 through the cooling fluid supply line 637b. The cooling fluid flowing through the cooling flow path 637 may cool the body 630. The substrate “W” may also be cooled by means of the body 630.

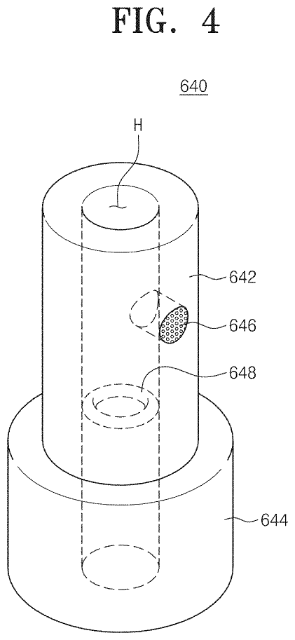

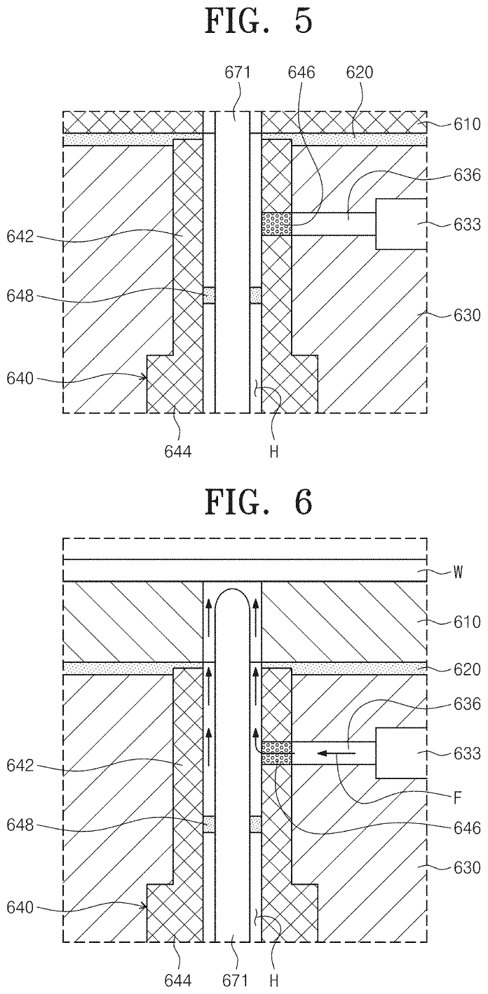

FIG. 4 is a schematic perspective view illustrating a lift pin bush of FIG. 2 according to the embodiment. FIG. 5 is a partially enlarged view of a support unit of FIG. 2 according to the embodiment. Hereinafter, the lift pin bush according to the embodiment of the inventive concept will be described in detail with reference to FIGS. 2 to 5.

The lift pin bush 640 may be disposed inside the body 630. According to the embodiment, the lift pin bush 640 may be inserted into the body 630. A material of the lift pin bush 640 may include a material having strong plasma resistance. According to the embodiment, the material of the lift pin bush 640 may include ceramics.

The lift pin bush 640 includes the upper portion 642 and a lower portion 644. The upper portion 642 and the lower portion 644 are formed integrally. The upper portion 642 and the lower portion 644 may be formed in a cylindrical shape having a hollow therein. The hollow may constitute a portion of a pin hole “H”, which will be described below. That is, the lift pin 671, which will be described below, may be elevated through the hollow. Hereinafter, for convenience of description, a hollow formed in the upper portion 642 and the lower portion 644 is commonly referred to as the pin hole “H”.

According to the embodiment, the upper portion 642 may be formed in a cylindrical shape having a first diameter. Further, the lower portion 644 may be formed in a cylindrical shape having a second diameter greater than the first diameter. When viewed from the front side, a lower surface of the lower portion 644 may be positioned at the same height as a lower surface of the body 630. Further, when viewed from the front side, an upper surface of the upper portion 642 may be positioned between the lower surface of the support plate 610 and the upper surface of the body 630. That is, an upper surface of the lift pin bush 640 may protrude upward from the upper surface of the body 630. The upper surface of the lift pin bush 640 and the lower surface of the support plate 610 may adhere by the adhesive layer 620.

A connection portion 646 is formed on a side surface of the lift pin bush 640. The connection portion 646 may include a material having strong plasma resistance. According to the embodiment, the material of the connection portion 646 may include ceramics. According to the embodiment, the connection portion 646 may be formed on a side surface of the upper portion 642. The connection portion 646 may be sintered together with the upper portion 642. The connection portion 646 and the upper portion 642 may be chemically or thermally sintered together. Accordingly, the connection portion 646 is formed integrally with the upper portion 642.

Further, the connection portion 646 may include a porous structure.

That is, the connection portion 646 may have a structure in which fine holes are formed. According to the embodiment, the entire region of the connection portion 646 may be formed in a porous structure. Optionally, only a portion of the entire region of the connection portion 646 may be formed in a porous structure. For example, as will be described below, the connection portion 646 may be connected to the second flow path 636, and only a portion connected to the second flow path 636 among the entire region of the connection portion 646 may be formed in a porous structure. However, the inventive concept is not limited thereto, and the porous structure formed in the connection portion 646 may be variously modified within the scope of the region that may cover the entire region connected to the second flow path 636. As will be described below, since an arcing phenomenon that may occur from the plasma introduced through the pin hole “H” may be suppressed by the porous structure formed in the connection portion 646, it is preferable that the porous structure be formed on the entire region of the connection portion 646. Hereinafter, for convenience of understanding, an example in which the entire region of the connection portion 646 is formed in the porous structure will be described.

The connection portion 646 may be connected to the second flow path 636. The connection portion 646 may allow the second flow path 636 and the pin hole “H” to be in fluid communication with each other. Accordingly, the heat transfer medium may be supplied from the second flow path 636 through the connection portion 646 to the pin hole “H”.

When viewed from a longitudinal cross section, the connection portion 646 may have a substantially circular shape. A diameter of the connection portion 646 may correspond to a diameter of the second flow path 636 or be greater than the diameter of the second flow path 636. However, the inventive concept is not limited thereto, and the connection portion 646 may be changed into various shapes, but the connection portion 646 may be formed in a shape that may cover the entire region of the second flow path 636 when viewed from the longitudinal cross section.

An O ring 648 may be disposed inside the lift pin bush 640. For example, the O ring 648 may be disposed in the hollow (the pin hole “H”) formed inside the lift pin bush 640. The O ring 648 may have a substantially ring shape. The O ring 648 may seal an outer surface of the lift pin 671, which will be described below, and a side surface of the pin hole “H”. When viewed from the front side, the O ring 648 may be positioned below the connection portion 646.

FIG. 6 is a schematic view illustrating a state in which a heat transfer medium flows inside the pin hole of FIG. 5 according to the embodiment. Hereinafter, a mechanism in which the heat transfer medium according to the embodiment of the inventive concept flows will be described in detail with reference to FIG. 6.

A heat transfer medium “F” may be supplied to the central flow path 633 and the edge flow path 634 (see FIG. 2) while plasma is generated in the treatment space 501 (see FIG. 2). The heat transfer medium “F” is supplied from the central flow path 633 sequentially through the second flow path 636 and the connection portion 646 to the pin hole “H”. That is, the heat transfer medium “F” is supplied to a space between the outer surface of the lift pin 671 and the side surface of the pin hole “H”.

A downward flow of the heat transfer medium “F” supplied into the pin hole “H” is restricted by the O ring 648. Accordingly, the heat transfer medium “F” flows along the pin hole “H” in an upward direction and is supplied to the lower surface of the substrate “W”. The heat transfer medium supplied to the lower surface of the substrate “W” may adjust a temperature of the substrate “W” to a predetermined temperature.

In general, the plasma generated in the treatment space 501 (see FIG. 2) may penetrate into a fine separation space between the lower surface of the substrate “W” and the upper surface of the support plate 610. In particular, the plasma may penetrate into the pin hole “H” formed in the support plate 610. Members arranged adjacent to the pin hole “H” are exposed to the plasma penetrating into the pin hole “H”. When the members exposed to the plasma include a material having relatively weak plasma resistance, such members may be arced by the penetrating plasma.

The adhesive layer 620 having relatively weak plasma resistance is highly likely to be arced by the penetrating plasma. In particular, the adhesive layer 620 between the upper surface of the lift pin bush 640 and the lower surface of the support plate 610 is positioned very close to the pin hole “H”, and thus has a relatively high risk of being arced by the plasma penetrating into the pin hole “H”.

Accordingly, according to the embodiment of the inventive concept, the heat transfer medium “F” is supplied to the pin hole “H”, the heat transfer medium supplied to the pin hole “H” flows upward, and thus a temperature of the adhesive layer 620 adjacent to the pin hole “H” may be adjusted. Accordingly, the arcing of the adhesive layer 620 by the plasma penetrating into the pin hole “H” may be minimized.

When the heat transfer medium is directly supplied to the pin hole “H”, one end of the flow path (for example, the second flow path 636) connected to the pin hole “H” may be arced by the plasma penetrating into the pin hole “H”. Accordingly, according to the embodiment of the inventive concept, the lift pin bush 640 having a hollow therein forming a portion of the pin hole “H” may be disposed inside the body 630. Since a material of the lift pin bush 640 according to the embodiment includes a material having strong plasma resistance, a possibility that the lift pin bush 640 is arced by the plasma penetrating into the pin hole “H” is relatively low.

Further, according to the embodiment of the inventive concept, the connection portion 646 may be formed on the side surface of the lift pin bush 640 to supply the heat transfer medium to the pin hole “H”. Since the connection portion 646 according to the embodiment includes a material having strong plasma resistance, a possibility that the connection portion 646 is arced by the plasma penetrating into the pin hole “H” is remarkably low.

In general, when joint portions or steps are present in structures positioned in the plasma penetrating regions, a possibility that electric charges occur increases. According to the embodiment of the inventive concept, the connection portion 646 may be sintered together with the lift pin bush 640 and formed integrally with lift pin bush 640. Accordingly, there is no joint portion between the lift pin bush 640 and the connection portion 646. That is, the connection portion 646 according to the embodiment of the inventive concept is formed integrally with the lift pin bush 640, and thus a risk that the connection portion 646 is arced by the plasma penetrating into the pin hole “H” may be minimized.

In general, the arcing phenomenon caused by the plasma intensifies as an exposure area of the member exposed to the plasma increases. For example, when the plasma is introduced into a member having a relatively large diameter, the member having a large diameter is arced relatively more easily by the plasma than a member having a small diameter. Accordingly, according to the embodiment of the inventive concept, since the connection portion 646 includes a porous structure in which fine holes are formed, the arcing of the connection portion 646 by the penetrating plasma may be minimized even when the plasma penetrates into the connection portion 646 through the pin hole “H”.

Further, according to the embodiment of the inventive concept, an inner surface of the second flow path 636 may be anodized. As the inner surface of the second flow path 636 is anodized, a discharge phenomenon caused by the plasma may be suppressed even when a portion of the plasma penetrating into the pin hole “H” passes through the connection portion 646 and penetrates into the second flow path

Accordingly, since the second flow path 636 that supplies the heat transfer medium is in flow communication with the pin hole “H” by means of the connection portion 646, a risk that the second flow path 636 is arced by the plasma penetrating into the pin hole “H” may be minimized.

Further, according to the embodiment of the inventive concept, the main flow path 632 and the second flow path 636 may be arranged at heights corresponding to the upper portion 642 of the lift pin bush 640 . The upper portion 642 of the lift pin bush 640 has a smaller diameter than that of the lower portion 644. Accordingly, since a space in which the main flow path 632 and the second flow path 636 are arranged inside the body 630 may be efficiently secured, structural complexity may be resolved.

Referring back to FIG. 2, the insulation plate 650 is positioned below the body 630. The insulation plate 650 may include an insulating material. The insulation plate 650 electrically insulates the body 630 and the lower cover 660, which will be described below. The insulation plate 650 may have a substantially circular shape when viewed from the upper portion. The insulation plate 650 may have an area corresponding to the body 630.

The lower cover 660 is positioned below the insulation plate 650. When viewed from the upper portion, the lower cover 660 may have a cylindrical shape with an open upper surface. An upper surface of the lower cover 660 may be covered by the insulation plate 650. A lift pin assembly 670, which will be described below, may be positioned in an inner space of the lower cover 660.

The lower cover 660 may include a plurality of connection members 662. The connection members 662 may connect an outer surface of the lower cover 660 and an inner wall of the housing 500 to each other. The plurality of connection members 662 may be arranged spaced apart from each other in a circumferential direction of the lower cover 660. The connection members 662 support the support unit 600 inside the housing 500. Further, the connection member 662 may be connected to the grounded housing 500 to ground the lower cover 660.

The lift pin assembly 670 elevates the substrate “W”. The lift pin assembly 670 elevates the substrate “W” supported by the support plate 610. The lift pin assembly 670 may include the lift pin 671 and an elevation plate 672.

The lift pin 671 may elevate along the pin hole “H” formed inside the support unit 600. A diameter of the lift pin 671 may be relatively smaller than a diameter of the pin hole “H”. Further, an upper end of the lift pin 671 may be rounded. The lift pin 671 may be provided as a plurality of lift pins 671. For example, three lift pins 671 may be provided. The elevation plate 672 may be positioned in the inner space of the lower cover 660. The elevation plate 672 may move in the vertical direction by a driving member that is not illustrated. Accordingly, the elevation plate 672 may elevate the lift pin 671.

The gas supply unit 700 supplies the gas to the treatment space 501. The gas supply unit 700 may include a gas supply nozzle 710, a gas supply line 720, and a gas supply source 730.

The gas supply nozzle 710 may be installed in a central region of an upper surface of the housing 500. An injection port (not illustrated) is formed on a bottom surface of the gas supply nozzle 710. The injection port (not illustrated) may inject a gas into the housing 500.

One end of the gas supply line 720 is connected to the gas supply nozzle 710. The other end of the gas supply line 720 is connected to the gas supply source 730. The gas supply source 730 may store the gas. The gas may be a gas excited into a plasma state by a plasma source, which will be described below. According to the embodiment, the gas may include NH₃, NF₃ and/or an inert gas. A gas valve 740 is installed in the gas supply line 720. The gas valve 740 may be an opening or closing valve.

The plasma source excites the gas supplied into the housing 500 into a plasma state. A capacitively coupled plasma (CCP) may be used as the plasma source according to the embodiment of the inventive concept. However, the inventive concept is not limited thereto, and the gas supplied to the treatment space 501 may be excited into a plasma state using an inductively coupled plasma (ICP) or a microwave plasma. Hereinafter, an example of a case in which the CCP is used as the plasma source according to the embodiment will be described.

The plasma source may include an upper electrode and a lower electrode. The upper electrode and the lower electrode may be arranged to face each other inside the housing 500. High-frequency power may be applied to one electrode of the two electrodes, and the other electrode of the two electrodes may be grounded. Unlike this, the high-frequency power may be applied to both electrodes. An electric field may be formed in a space between the two electrodes, and the gas supplied to the space may be excited into a plasma state. A substrate treatment process is performed by the plasma. According to the embodiment, the upper electrode may be an electrode plate 830, which will be described below, and the lower electrode may be the body 630.

The shower head unit 800 is positioned inside the housing 500. Further, the shower head unit 800 is positioned above the support unit 600. The shower head unit 800 may include a shower plate 810, the electrode plate 830, and a support part 850.

The shower plate 810 is positioned above the support unit 600 to face the support unit 600. The shower plate 810 may be spaced apart from a ceiling surface of the housing 500 in a downward direction. According to the embodiment, the shower plate 810 may have a disk shape having a constant thickness. The shower plate 810 may be an insulator. A plurality of through-holes 812 are formed in the shower plate 810.

The through-holes 812 may pass through an upper surface and a lower surface of the shower plate 810. The through-hole 812 is positioned to face a hole 832 formed in the electrode plate 830, which will be described below.

The electrode plate 830 is located above the shower plate 810. The electrode plate 830 may be spaced a predetermined distance from the ceiling surface of the housing 500 in the downward direction. Accordingly, a space may be formed between the electrode plate 830 and the ceiling surface of the housing 500. The electrode plate 830 may have a disk shape having a constant thickness.

A material of the electrode plate 830 may include a metal. The electrode plate 830 may be grounded. However, as described above, the electrode plate 830 may be electrically connected to the high frequency power source (not illustrated). A bottom surface of the electrode plate 830 may be anodized to minimize the arcing by the plasma. A cross section of the electrode plate 830 may have the same shape and the same cross section as those of the support unit 600.

A plurality of holes 832 are formed in the electrode plate 830. The holes 832 penetrate an upper surface and a lower surface of the electrode plate 830. The plurality of holes 832 correspond to the plurality of through-holes 812 arranged in the shower plate 810, respectively. Accordingly, the gas injected from the gas supply nozzle 710 flows to a space formed by combining the electrode plate 830 and the housing 500 with each other. The gas may be supplied from the space via the hole 832 and the through-hole 812 to the treatment space 501.

The support part 850 supports a side portion of the shower plate 810 and a side portion of the electrode plate 830. An upper end of the support part 850 is connected to the ceiling surface of the housing 500, and a lower portion of the support part 850 is connected to the side portion of the shower plate 810 and the side portion of the electrode plate 830. A material of the support part 850 may include non-metal.

In the embodiment of the inventive concept, an example in which the connection portion 646 is formed in the upper portion 642 of the lift pin bush 640 has been described, but the inventive concept is not limited thereto. The connection portion 646 may be formed on a side surface of the lower portion 644. Further, the connection portion 646 may be sintered at the same time as the lower portion 644.

Hereinafter, a heat transfer flow path according to another embodiment will be described. Since the heat transfer flow path according to the embodiment, which will be described below, has substantially the same as or similar to the configuration of the heat transfer flow path described with reference to FIGS. 2 to 6 except for additional description, a description of the duplicated configuration will be omitted.

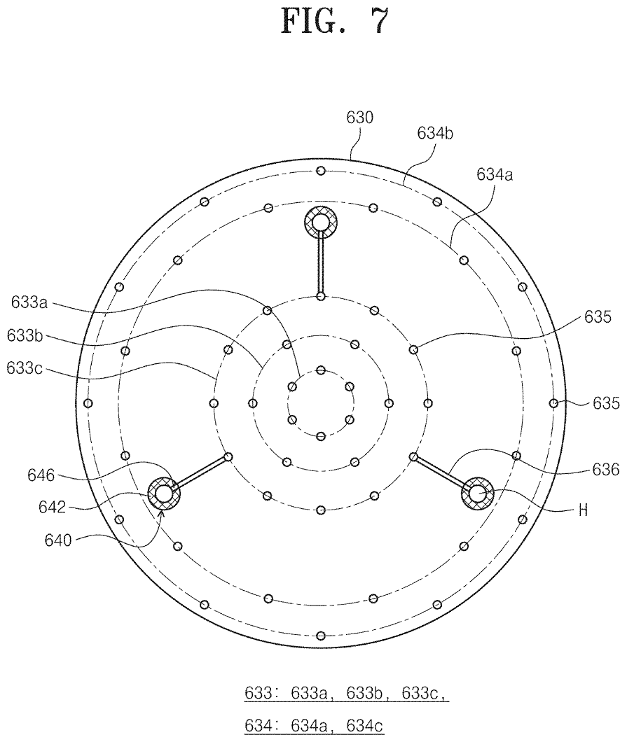

FIG. 7 is a schematic view illustrating a main flow path of FIG. 2 according to another embodiment when viewed from the upper portion.

Referring to FIG. 7, the central flow path 633 may include a plurality of flow paths. For example, the central flow path 633 may include a first central flow path 633a, a second central flow path 633b, and a third central flow path 633c. The first central flow path 633a, the second central flow path 633b, and the third central flow path 633c may have a substantially circular shape when viewed from the upper portion. The first central flow path 633a, the second central flow path 633b, and the third central flow path 633c may share the center of the body 630 and have different diameters.

For example, the first central flow path 633a may be positioned adjacent to the center of the body 630, and the second central flow path 633b may be positioned to surround the first central flow path 633a. Further, the third central flow path 633c may be positioned to surround the second central flow path 633b. According to the embodiment, the second flow path 636 may be connected to the third central flow path 633c among the first central flow path 633a, the second central flow path 633b, and the third central flow path 633c. Accordingly, the pin hole “H” and the third central flow path 633c may be in fluid communication with each other.

The edge flow path 634 may include a plurality of flow paths. For example, the edge flow path 634 may include a first edge flow path 634a and the second edge flow path 634b. The first edge flow path 634a and the second edge flow path 634b may have a substantially circular shape when viewed from the upper portion. The first edge flow path 634a and the second edge flow path 634b may share the center of the body 630 and have different diameters. The second edge flow path 634b may be positioned to surround the first edge flow path 634a.

Unlike the above description, description, the first central flow path 633a, the second central flow path 633b, and the third central flow path 633c may be connected to each other to be in fluid communication with each other. Further, the central flow path 633 may include two or four or more flow paths. Further, the first edge flow path 634a and the second edge flow path 634b may be connected to each other to be in fluid communication with each other. Further, the edge flow path 634 may include three or more flow paths.

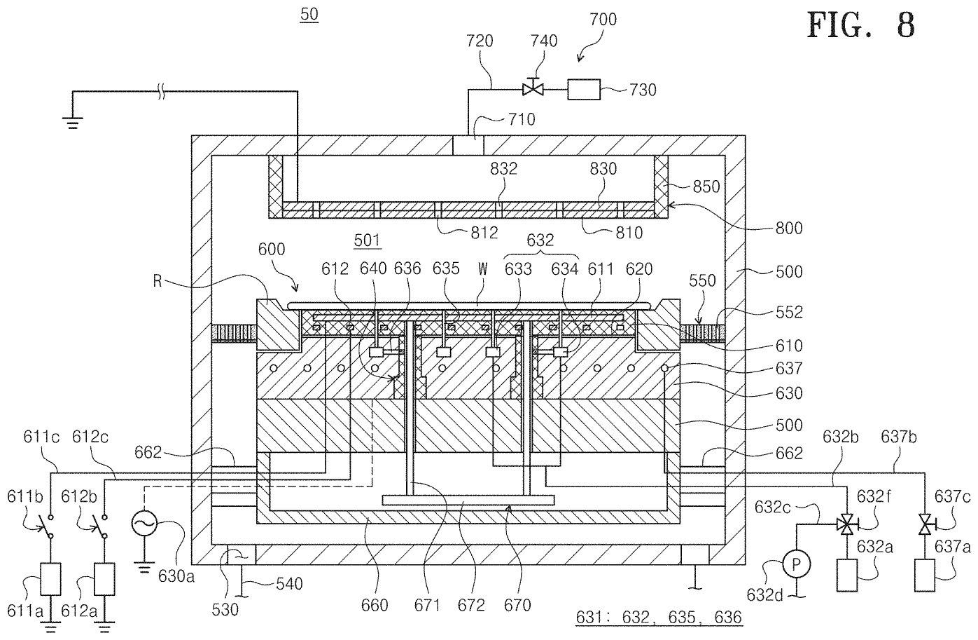

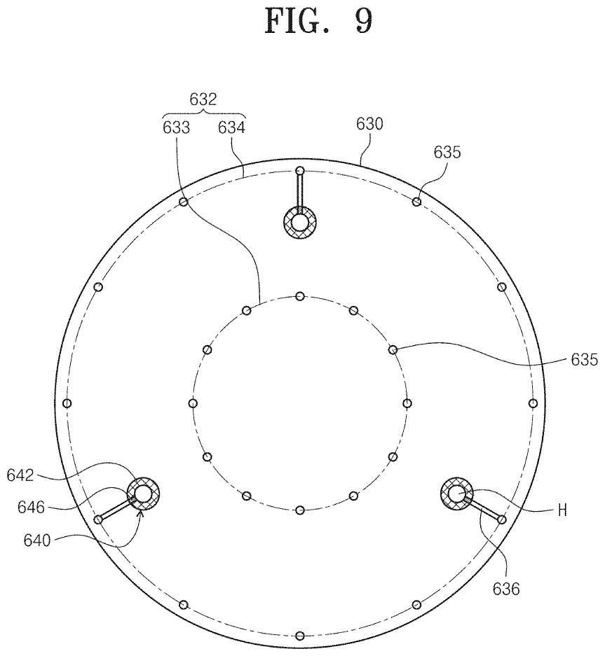

FIG. 8 is a schematic view illustrating a process chamber of FIG. 2 according to another embodiment. FIG. 9 is a schematic view illustrating the main flow path of FIG. 7 according to the embodiment when viewed from the upper portion.

Referring to FIGS. 8 and 9, the second flow path 636 may be connected to the edge flow path 634. That is, the second flow path 636 may allow the edge flow path 634 and the pin hole “H” to be in fluid communication with each other. Accordingly, the heat transfer medium may be supplied from the edge flow path 634 to the pin hole “H”.

Although not illustrated, a portion of the second flow path 636 may be connected to the central flow path 633, and the other portion thereof may be connected to the edge flow path 634. Accordingly, the second flow path 636 may allow the central flow path 633 and the pin hole “H” to be in fluid communication with each other or allow the edge flow path 634 and the pin hole “H” to be in flow communication with each other. Further, the central flow path 633 and the edge flow path 634 described with reference to FIGS. 2 to 9 may be formed in a spiral shape when viewed from the upper portion.

According to an embodiment of the inventive concept, occurrence of an arcing phenomenon by plasma may be minimized.

Further, according to an embodiment of the inventive concept, occurrence of the arcing phenomenon by the plasma in the vicinity of a pin hole may be minimized.

Further, according to an embodiment of the inventive concept, a heat transfer medium is supplied to a lower surface of a substrate through the pin hole to adjust a temperature of the substrate, and at the same time, to adjust a temperature inside the pin hole.

Further, according to an embodiment of the inventive concept, structural complexity of the substrate treatment apparatus may be minimized.

The effects of the inventive concept are not limited to the above-mentioned effects, and the unmentioned effects can be clearly understood by those skilled in the art to which the inventive concept pertains from the specification and the accompanying drawings.

The above detailed description exemplifies the inventive concept. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to restrict the inventive concept in the disclosed embodiment state. Furthermore, it should be construed that the attached claims include other embodiments.

What is claimed is:

1. A substrate treatment apparatus for treating a substrate, the apparatus comprising:
a housing having a treatment space in which the substrate is treated;
a support unit configured to support the substrate in the treatment space; and
a gas supply unit configured to supply a gas to the treatment space,
wherein a heat transfer flow path configured to supply a heat transfer medium to the substrate supported by the support unit, a pin hole defining an elevation path of a lift pin configured to elevate the substrate supported by the support unit, and a connection portion allowing the heat transfer flow path and the pin hole to be in communication with each other are formed inside the support unit, and
the connection portion includes a porous structure.

2. The substrate treatment apparatus of claim 1, wherein the support unit includes:
a support plate configured to support the substrate; and
a body which is positioned below the support plate and in which high frequency power is applied to generate plasma in the treatment space,
a lift pin bush having a hollow therein forming a portion of the pin hole is disposed inside the body, and
the connection portion is formed on a side surface of the lift pin bush.

3. The substrate treatment apparatus of claim 2, wherein the connection portion is formed integrally with the side surface of the lift pin bush.

4. The substrate treatment apparatus of claim 2, wherein an O ring configured to seal an outer surface of the lift pin and a side surface of the hollow is disposed in the hollow, and
the O ring is positioned below the connection portion when viewed from the front side.

5. The substrate treatment apparatus of claim 2 wherein the heat transfer flow path includes:
a main flow path which is formed inside the body and through which the heat transfer medium circulates;
a first flow path connected to the main flow path, formed in a vertical direction inside the body and the support plate, and configured to supply the heat transfer medium to a lower surface of the substrate; and
a second flow path formed inside the body and connecting the main flow path and the connection portion.

6. The substrate treatment apparatus of claim 5, wherein a diameter of the second flow path corresponds to a diameter of the connection portion or is smaller than the diameter of the connection portion.

7. The substrate treatment apparatus of claim 5, wherein a lower surface of the support plate and an upper surface of the body adhere to each other by an adhesive layer.

8. The substrate treatment apparatus of claim 7, wherein each of the lift pin bush and the connection portion includes a material having relatively higher plasma resistance than the adhesive layer and the second flow path.

9. The substrate treatment apparatus of claim 8, wherein a material of each of the lift pin bush and the connection portion includes ceramics.

10. The substrate treatment apparatus of claim 5, wherein a surface of the second flow path is anodized.

11. The substrate treatment apparatus of claim 5, wherein the main flow path includes:
a central flow path formed in a central region including a center of the body; and
an edge flow path formed in an edge region surrounding the central region, and
the second flow path connects the central flow path and/or the edge flow path and the connection portion.

12. The substrate treatment apparatus of claim 5, wherein the plurality of pin holes are formed inside the support unit,
the plurality of second flow paths are formed inside the body, and
the plurality of pin holes are in fluid communication with the plurality of second flow paths, respectively.

13. A substrate treatment apparatus for treating a substrate, the apparatus comprising:
a housing having a treatment space in which the substrate is treated;
a support unit configured to support the substrate in the treatment space;
a gas supply unit configured to supply a gas to the treatment space; and
a plasma source configured to generate plasma by exciting the gas,
wherein the support unit includes:
a heat transfer flow path formed inside the support unit and configured to supply a heat transfer medium to the substrate supported by the support unit;
a lift pin bush disposed inside the support unit and having a hollow formed therein; and
a lift pin elevated through the hollow and configured to elevate the substrate supported by the support unit,
a connection portion including a porous structure is formed on a side surface of the lift pin bush, and
the heat transfer flow path is connected to the connection portion.

14. The substrate treatment apparatus of claim 13, wherein the connection portion and the lift pin bush are simultaneously sintered and integrally formed.

15. The substrate treatment apparatus of claim 14, wherein an upper portion of the lift pin bush has a first diameter, and a lower portion of the lift pin bush has a second diameter greater than the first diameter, and
the connection portion is formed above the lift pin bush.

16. The substrate treatment apparatus of claim 13, wherein the support unit further includes:
a support plate configured to support the substrate; and
a body which is positioned below the support plate and in which high frequency power is applied to generate the plasma in the treatment space,
the heat transfer flow path is formed inside the body,
the lift pin bush is disposed inside the body,
an upper surface of the lift pin bush is positioned between an upper surface of the body and a lower surface of the support plate, and
the lower surface of the support plate and the upper surface of the body and the lower surface of the support plate and the upper surface of the lift pin bush adhere to each other by an adhesive layer.

17. The substrate treatment apparatus of claim 16, wherein each of the lift pin bush and the connection portion includes a material having relatively stronger plasma resistance than the adhesive layer.

18. The substrate treatment apparatus of claim 13, wherein an O ring configured to seal an outer surface of the lift pin and a side surface of the hollow is disposed in the hollow.

19. The substrate treatment apparatus of claim 18, wherein the O ring is positioned below the connection portion when viewed from the front side.

20. A substrate treatment apparatus for treating a substrate, the apparatus comprising:
a housing having a treatment space in which the substrate is treated;
a support unit configured to support the substrate in the treatment space;
a gas supply unit configured to supply a gas to the treatment space; and
a plasma source configured to generate plasma by exciting the gas,
wherein the support unit includes:
a support plate configured to support the substrate;
a body which is positioned below the support plate and in which high frequency power is applied to generate the plasma in the treatment space;
a heat transfer flow path formed inside the body and configured to supply a heat transfer medium to the substrate supported by the support unit;
a lift pin bush disposed inside the body and having a hollow formed therein; and
a lift pin elevated through the hollow and configured to elevate the substrate supported by the support unit from the support plate,
the heat transfer flow path includes:
a main flow path which is formed inside the body and through which the heat transfer medium circulates;
a first flow path connected to the main flow path, formed inside the body and the support plate in a vertical direction, and configured to supply the heat transfer medium to a lower surface of the substrate; and
a second flow path formed inside the body and configured to allow the main flow path and the hollow to be in fluid communication with each other,
a connection portion having a porous structure is integrally formed on a side surface of the lift pin bush, and
one end of the second flow path is connected to the connection portion.
